(19) United States
(12) Patent Application Publication
(10) Pub. No.: US 2015/0201513 A1
(43) Pub. Date: Jul. 16, 2015

(54) ELECTRONIC MODULE WITH TAMPER PROTECTION

(71) Applicant: ROSCH HOLDING UND CONSULTING GMBH, Muenchen (DE)

(72) Inventors: Istvan Czobel, Quarten (CH); Robert Schneider, Salzburg (AT)

(73) Assignee: Rosch Holding und Consulting GmbH, Muenchen (DE)

(21) Appl. No.: 14/417,464

(22) PCT Filed: Jul. 26, 2013
(86) PCT No.: PCT/EP2013/065808

§ 371 Date: Jan. 26, 2015

(30) Foreign Application Priority Data
Jul. 27, 2012 (DE) 20 2012 007 236.6

(51) Int. Cl. H05K 5/06; H05K 7/14; H05K 5/03

(52) U.S. Cl. CPC H05K 5/065; H05K 5/03; H05K 7/1427

(57) ABSTRACT

A tamper-protected electronic module comprises a printed circuit board having a first side, on which electronic components of an electronic circuit including at least one microchip are located, and a housing cover that is facing the first side of the printed circuit board. The housing cover has, on the inside thereof, a sealed inner frame that extends to the first side of the printed circuit board and surrounds only a security-relevant portion of the electronic circuit including the microchip. The volume enclosed by the inner frame between the first side of the printed circuit board and the housing cover is filled with a casting resin under formation of a coherent casting compound.

The invention relates to a tamper-protected electronic module, in particular for carrying out secure transactions (e.g. in cashless payments), the verification of individuals (e.g. in connection with an electronic identity card) or similar applications (e.g. in connection with an electronic health card).

It is known to encapsulate electronic components or circuits by casting them using a casting resin. Casting is usually used as a protection from environmental influences (moisture, dust etc.), as an electrical insulation or in order to enhance the mechanical stability of the encapsulated components. A further application is the protection of electronic components or circuits, in which operations with confidential data are carried out, from tampering by third parties.

It is the object of the invention to make the tamper protection in an electronic module as effective and cost-efficient as possible.

This object is achieved by an electronic module having the features of claim 1. Advantageous and expedient embodiments of the electronic module according to the invention are set forth in the sub-claims.

The tamper-protected electronic module according to the invention is provided in particular for carrying out secure transactions (e.g. in cashless payments), the verification of individuals (e.g. in connection with an electronic identity card) or similar applications (e.g. in connection with an electronic health card) and comprises a printed circuit board having a first side, on which electronic components of an electronic circuit including at least one microchip are located, and a housing cover that is facing the first side of the printed circuit board. According to the invention, the housing cover has, on the inside thereof, a sealed inner frame that extends to the first side of the printed circuit board and only surrounds a security-relevant portion of the electronic circuit including the microchip. The volume enclosed by the inner frame between the first side of the printed circuit board and the housing cover is filled with a casting resin under formation of a coherent casting compound.

The invention is based on the finding that it is not absolutely necessary to protect the entire circuit of one or more printed circuit boards from tampering attempts. Rather, it is sufficient to secure those parts of the circuit in which security-relevant operations with confidential data are carried out. By way of a clever placement on the printed circuit board, these parts can be locally combined to form a security-relevant portion of the electronic circuit. According to the invention it is possible, due to the delimitation by the inner frame, to deliberately fill only this area, thus making it inaccessible. Thus, compared to filling the entire circuitry, a substantial amount of casting resin can be saved. This reduces the manufacturing costs of the electronic module, in particular with a view to a serial production of large quantities. By connecting the coherent casting compound with the printed circuit board and the housing cover, however, a very high level of security is achieved, because it is not readily possible to lift the housing cover off from the printed circuit board.

According to the preferred embodiment of the electronic module according to the invention, the printed circuit board does not include any elevations in the locations that are directly facing the inner frame. As a result, in the case of a planar printed circuit board and a planar cover surface of the housing cover, a simple design with an inner frame that may have the same height throughout becomes possible, in order to ensure resting with the entire surface on the printed circuit board and thus optimal sealing.

Security from tampering attempts can be enhanced even further by ensuring that the casting compound extends into an area between the microchip and the first side of the printed circuit board. In the case of an attempt to remove the housing cover from the printed circuit board, the microchip will be forcefully detached from the printed circuit board, because the casting compound underneath the microchip is coherent with the casting compound that adheres to the housing cover. As a result, the pull-off forces are transferred onto the microchip in an extremely effective manner.

In a further security measure that may additionally be provided, a loosely wound coil is provided as part of the electronic circuit, which coil is located in the security-relevant portion, and the casting compound extends between the windings of the coil. Such a coil, which does not need to fulfil a specific task in conjunction with the actual function of the electronic module, may serve as a reliable indicator for a forceful mechanical action. Since the casting compound is located between the windings, windings will be torn off from the coil in the case of a forceful mechanical action. However, the proper condition of the coil can be verified at any time in a simple manner through the electronic circuit, so that any tampering attempt is immediately detectable.

To ensure that the casting resin can, during the injection thereof, penetrate into the above-mentioned or other narrow or hardly accessible areas, the casting resin should, prior to curing, have a viscosity of less than 2.5 Pas, preferably less than 2.0 Pas.

Preferably, a polyurethane resin is used as a casting resin, in particular a two-component mixture of a resin and a curing agent.

According to a particular aspect of the invention that relates to the production of the electronic module according to the invention, the printed circuit board has at least two bores within the security-relevant portion, which extend from the first surface to the opposite second surface of the printed circuit board. The bores allow, in a simple manner, a resistance-free injection of the casting resin into the security-relevant portion, which would otherwise be hermetically sealed by the inner frame, the printed circuit board and the housing cover. In this way however, whilst the casting resin is introduced through one bore, the air in the hermetically sealed area can at the same time escape through the other bore. If the enclosed air volume could not escape, this would impede or even render impossible any further injection of casting resin.

The invention will be described below by way of a preferred embodiment with reference to the attached drawings, wherein:

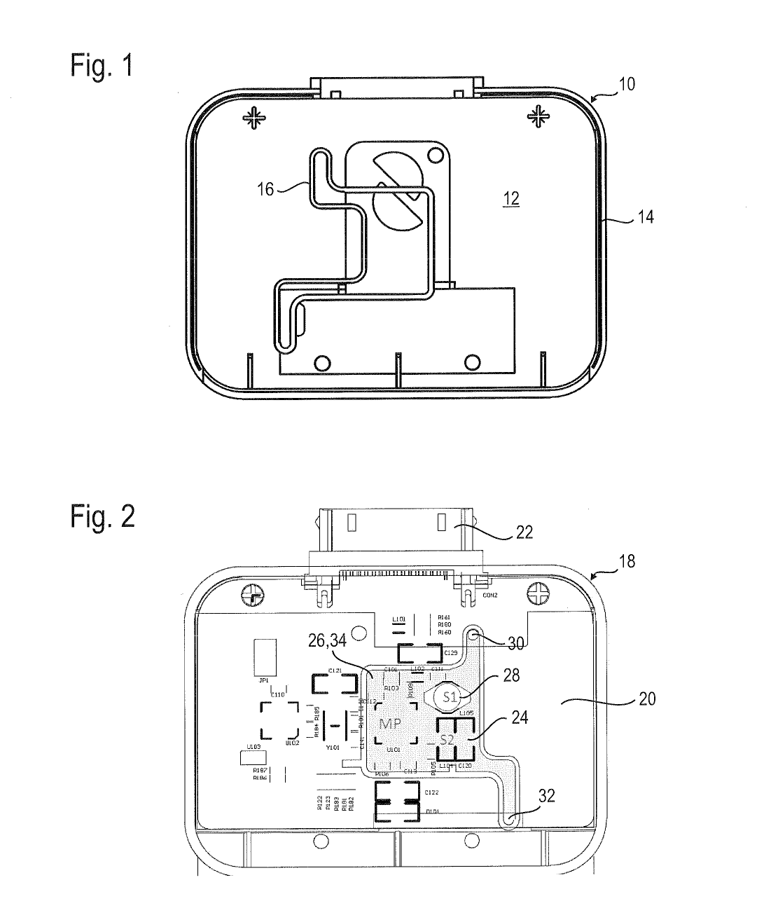

FIG. 1 shows a top view of the inside of a housing cover of an electronic module according to the invention; and

FIG. 2 shows a top view of a fully assembled electronic module according to the invention without the housing cover.

FIG. 1 shows a housing cover 10 of an electronic module that is provided for use in cashless payment transactions. The housing cover 10 is substantially made from plastic and can be produced using an injection moulding method. The housing cover 10 includes a closed cover surface 12 with an outer frame 14 that extends, according to the representation in FIG. 1, on the inside from the paper level upwards. The frame 14, which surrounds the outer periphery of the cover surface 12, is interrupted only in one place for the passage of a plug-in connector.

Apart from the outer frame 14, the housing cover 10 also includes a sealed inner frame 16 that has no interruptions. The inner frame 16, like the outer frame 14, also extends on the inside from the cover surface 12 upwards and has a constant height. The particular arrangement and the particular profile (shape) of the inner frame 16 will be addressed in more detail below. The inner frame 16 and further elevations, holding and/or positioning elements of the housing cover 10 form a support structure for a printed circuit board.

FIG. 2 shows a housing base 18 that matches the housing cover 10 of FIG. 1, and a printed circuit board 20 in the fully assembled condition of the electronic module. The housing cover 10, which in this condition, compared to the representation of FIG. 1, is located with the inside downwards above the housing base 18 and the printed circuit board 20, was omitted in FIG. 2, in order to illustrate the interior of the electronic module.

The printed circuit board 20 includes an electronic circuit with a number of electronic components, including a plug-in connector 22 that protrudes outwards through the interruption in the outer frame 14 of the housing cover 10. Most of the electronic components and wires of the circuit are located on the side of the printed circuit board 20 that can be seen in FIG. 2, which faces the housing cover 10 in the assembled condition of the electronic module (referred to below as the first side of the printed circuit board 20). In the assembled condition, the inner frame 16 of the housing cover 10 contacts the first side of the printed circuit board 20 over the entire length thereof. In the contact locations, the printed circuit board 20 does not have any elevations, so that the inner frame 16 can rest on the entire surface of the printed circuit board 20.

The inner frame 16 delimits a particular area on the first side of the printed circuit board 20. Within this area, inter alia, a microchip 24 (e.g. an ASIC or a microprocessor) is located, in which operations with confidential data are carried out. The delimited area can therefore be referred to as a security-relevant portion 26 of the electronic circuit. In the security-relevant portion 26 of the electronic circuit, also a loosely wound coil 28 is provided. Within the security-relevant portion 26, the printed circuit board 20 has two bores 30, 32 that extend from the first side to the opposite second side of the printed circuit board 20.

The essential steps for assembling the electronic module will be explained below. To start with, the printed circuit board 20 is placed on the support structure of the housing cover 10 in such a way that the inner frame 16 comes into full surface contact with the printed circuit board 20 and surrounds the security-relevant portion 26 of the electronic circuitry.

Subsequently, a casting resin is injected through one of the bores 30, 32 in the printed circuit board 20, until the volume within the inner frame 16, which is delimited at the top and the bottom by the housing cover 10 and the printed circuit board 20, respectively, is completely filled with casting resin. The other one of the bores 32 and 30 allows, during the injection of the casting resin, the air entrapped in the volume to be displaced. Once the casting resin has cured, a solid, coherent casting compound 34 is formed that does not allow any direct access to the security-relevant portion 26 of the electronic circuit.

As a casting resin, a polyurethane resin is used that is mixed together from two components, a resin and a curing agent. Prior to the curing, the casting resin has a viscosity of less than 2.5 Pa·s, preferably less than 2.0 Pa·s. As a result of the low viscosity of the casting resin during injection, the casting resin also penetrates into the area between the microchip 24 and the first side of the printed circuit board 20 and this area also becomes part of the coherent casting compound 34. Also, the casting resin can penetrate between the windings of the loosely wound coil 28 and can cure there.

After the curing of the casting resin, the housing cover 10 with the printed circuit board 20 is placed on the housing base 18, so that the printed circuit board 20 is completely surrounded by the housing formed by the housing base 18 and the housing cover 10.

Whilst in the case of a tampering attempt the housing base 18 can be removed from the housing cover 10 and the printed circuit board 20, any lifting off of the housing cover 10 from the printed circuit board 20 is not readily possible because they are firmly connected to each other by the casting compound 34. However, if such an attempt is nevertheless made, the pulling action on the housing cover 10 will by necessity result in the destruction of the security-relevant portion 26 of the electronic circuit. In particular, such an attempt will cause, due to the coherent casting compound 34, the microchip 24 to be torn off from the printed circuit board 20, and windings will be torn off from the coil 28. The destruction of the coil 28 can be readily verified electronically by way of a resistance measurement or the like in periodic intervals, so that upon destruction, a tampering attempt can be immediately detected and corresponding measures can be taken.

The terms “housing cover”, “housing base” etc., as well as direction/position information such as “top”, “bottom” etc., as used in the description and in the following claims, are not to be understood in a limiting sense; they were merely chosen to allow a better distinction.

### LIST OF REFERENCE NUMERALS

10 Housing cover
12 Cover surface
14 Outer frame
16 Inner frame
18 Housing base
20 Printed circuit board
22 Plug-in connector
24 Microchip
26 Security-relevant portion
28 Coil
30 Bore
32 Bore
34 Casting compound

1. A tamper-protected electronic module comprising:
a printed circuit board having a first side, on which electronic components of an electronic circuit including at least one microchip are located, and
a housing cover facing the first side of the printed circuit board, wherein
the housing cover has, on the inside thereof, a sealed inner frame that extends to the first side of the printed circuit board and surrounds only a security-relevant portion of the electronic circuit including the microchip, and
the volume enclosed by the inner frame between the first side of the printed circuit board and the housing cover is filled with a casting resin under formation of a coherent casting compound.

2. The electronic module according to claim 1, wherein the printed circuit board does not include any elevations in the locations that are directly facing the inner frame.

3. The electronic module according to claim 1, wherein the casting compound extends into an area between the microchip and the first side of the printed circuit board.

4. The electronic module according to claim 1, wherein the circuit in the security-relevant portion includes a loosely wound coil, wherein the casting compound extends between the windings of the coil.

5. The electronic module according to claim 1, wherein the casting resin has, prior to curing, a viscosity of less than 2.5 Pa·s.

6. The electronic module according to claim 1, wherein the casting resin comprises a polyurethane resin.

7. The electronic module according to claim 1, wherein the printed circuit board has at least two bores within the security-relevant portion, which bores extend from the first side to an opposite second side of the printed circuit board.

8. The electronic module according to claim 1, wherein the casting resin has, prior to curing, a viscosity of less than 2.0 Pa·s.

9. The electronic module according to claim 1, wherein the casting resin comprises a two-component mixture of a resin and a curing agent.
